(19) United States
(12) Patent Application Publication
(10) Pub. No.: US 2025/0379370 A1
(43) Pub. Date: Dec. 11, 2025

(54) ELECTRONIC DEVICE COMPRISING CONDUCTIVE CONNECTOR

(71) Applicant: SAMSUNG ELECTRONICS CO., LTD., Suwon-si (KR)

(72) Inventors: Seonghun CHOI, Suwon-si (KR); Hyein PARK, Suwon-si (KR); Junyoung YANG, Suwon-si (KR); Jaedeok LIM, Suwon-si (KR); Taekkyun CHOI, Suwon-si (KR)

(73) Assignee: SAMSUNG ELECTRONICS CO., LTD., Suwon-si (KR)

(21) Appl. No.: 19/173,320

(22) Filed: Apr. 8, 2025

Related U.S. Application Data
(63) Continuation of application No. PCT/KR2025/003442, filed on Mar. 17, 2025.

(30) Foreign Application Priority Data
Jun. 7, 2024 (KR) 10-2024-0074610
Jul. 3, 2024 (KR) 10-2024-0087863

(51) Int. Cl. H01R 4/04; H05K 5/02

(52) U.S. Cl. CPC H01R 4/04; H05K 5/0247

(57) ABSTRACT

An electronic device includes: a bracket including a conductive portion; a display including a conductive layer; a conductive connector between the conductive layer of the display and the conductive portion of the bracket and contacts the conductive layer of the display; and a conductive adhesive attaching the conductive connector to the conductive portion of the bracket, wherein the conductive connector includes: an interior part including an elastic foam, an exterior part including a conductive woven fabric, a coating portion attached to an inner surface of the conductive woven fabric and attached to the exterior part, and an adhesive attaching the interior part to the coating portion.

### CROSS-REFERENCE TO RELATED APPLICATIONS

This application is a by-pass continuation application of International Application No. PCT/KR2025/003442, filed on Mar. 17, 2025, which is based on and claims priority to Korean Patent Application Nos. 10-2024-0074610, filed on Jun. 7, 2024, and 10-2024-0087863, filed on Jul. 3, 2024, in the Korean Intellectual Property Office, the disclosures of which are incorporated by reference herein their entireties.

### BACKGROUND

### 1. Field

The present disclosure relates to an electronic device including a conductive connector.

### 2. Description of Related Art

A portable electronic device may include an antenna or antenna circuitry for communication with an external device. A conductive portion within the electronic device may be used as a ground to secure the performance of the antenna and the antenna circuitry. The portable electronic device may include a conductive connector to connect a plurality of conductive portions.

The above-described information may be provided as related art for the purpose of helping to understand the present disclosure. No claim or determination is raised as to whether any of the above-described information may be applied as prior art related to the present disclosure.

### SUMMARY

An electronic device may comprise a bracket. The bracket may comprise a conductive portion. The electronic device may further comprise a display. The display may comprise a conductive layer. The electronic device may further comprise a conductive connector. The conductive connector may be disposed between the conductive layer of the display and the conductive portion of the bracket, and in contact with the conductive layer of the display. The electronic device may comprise a conductive adhesive. The conductive adhesive may attach the conductive connector to the conductive portion of the bracket. The conductive connector may comprise an interior part and an exterior part. The interior part may comprise an elastic foam. The exterior part may comprise a conductive woven fabric. The conductive connector may comprise a coating portion. The coating portion may be attached to an inner surface of the conductive woven fabric of the exterior part. The conductive connector may further comprise an adhesive. The adhesive may attach the interior part to the coating portion.

An electronic device may comprise a bracket, a display on the bracket, and a conductive connector electrically connecting a conductive portion of the bracket and a conductive layer of the display facing the conductive portion of the bracket. The conductive connector may comprise an elastic foam. The conductive connector may further comprise an adhesive on a first surface of the elastic foam facing the conductive layer of the display and a second surface of the elastic foam facing the conductive portion of the bracket. The conductive connector may comprise a coating at an outer surface of the adhesive. The conductive connector may comprise a conductive outer jacket disposed along an outer surface of the coating, contacted with the conductive portion of the bracket and the conductive layer of the display, and providing a conductive path between the conductive portion of the bracket and the conductive layer of the display. A portion of the coating may fill a groove portion at an outer surface of the conductive outer jacket.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates an electronic device according to an embodiment;

FIG. 2 is an exploded perspective view of an electronic device according to an embodiment;

FIG. 3 is a plan view illustrating a bracket of an electronic device according to an embodiment;

FIG. 4 is a cross-sectional view of an electronic device in which a portion where a conductive connector connecting a display and a bracket is disposed is cut, according to an embodiment;

FIG. 5 is an enlarged cross-sectional view a periphery of a conductive connector;

FIG. 6 is a perspective view of an example conductive connector;

FIG. 7 is a plan view of an example conductive connector;

FIG. 8 illustrates an example manufacturing process of a conductive connector;

FIG. 9A illustrates an example process of forming a coating fabric;

FIG. 9B illustrates an example process of coating a conductive woven fabric;

FIGS. 9C and 9D illustrate an example process of forming a conductive connector using a conductive woven fabric and an elastic foam; and

FIG. 10 is a block diagram of an electronic device in a network environment according to an embodiment.

### DETAILED DESCRIPTION

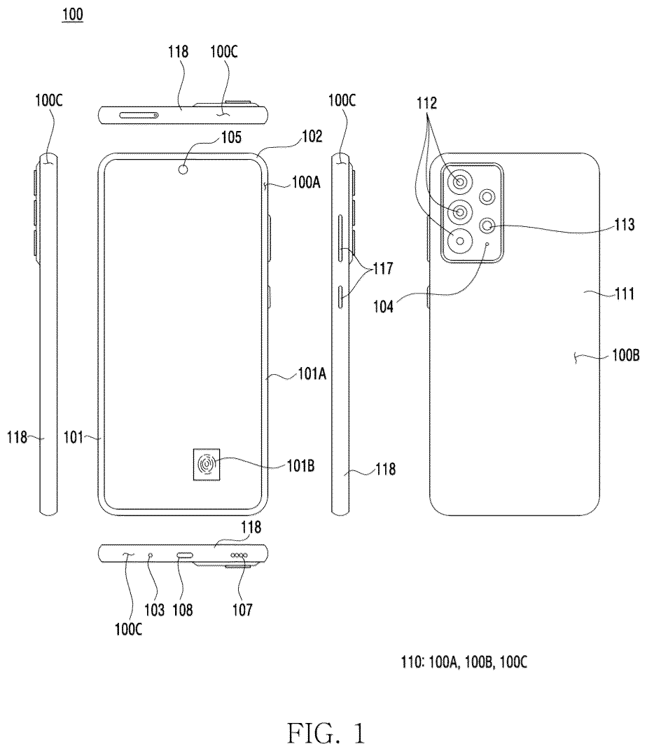

FIG. 1 illustrates an electronic device according to an embodiment.

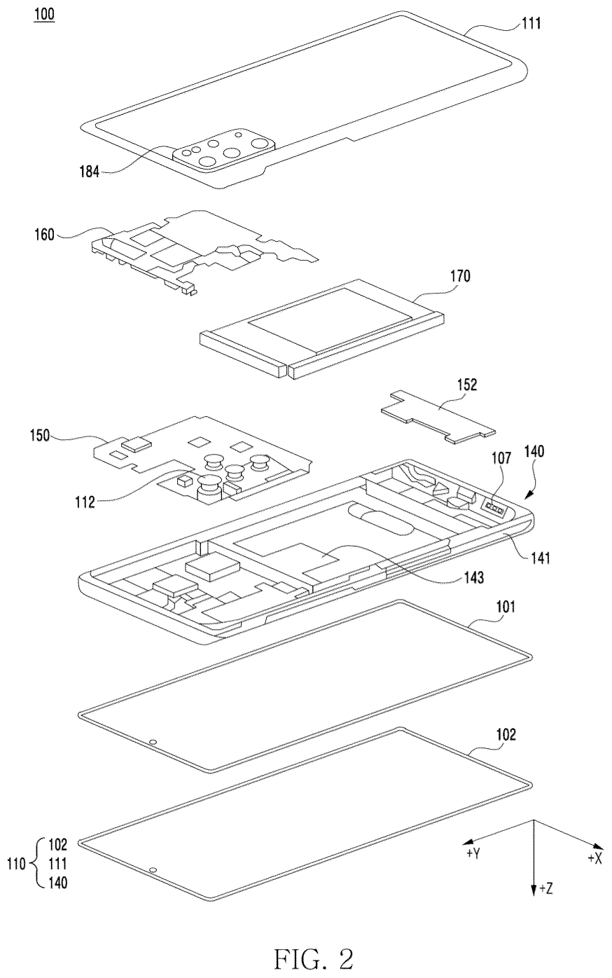

Referring to FIG. 1, an electronic device 100 according to an embodiment may include a housing 110 forming an exterior of the electronic device 100. For example, the housing 110 may include a first surface (or front surface) 100A, a second surface (or rear surface) 100B, and a third surface (or lateral surface) 100C surrounding a space between the first surface 100A and the second surface 100B. In an embodiment, the housing 110 may refer to a structure (e.g., a frame structure 140 of FIG. 2) forming at least a portion of the first surface 100A, the second surface 100B, and/or the third surface 100C.

The electronic device 100 according to an embodiment may include a substantially transparent front plate 102. In an embodiment, the front plate 102 may form at least a portion of the first surface 100A. In an embodiment, the front plate 102 may include, for example, a glass plate or a polymer plate that includes various coating layers, but the disclosure is not limited to the above embodiment.

The electronic device 100 according to an embodiment may include a substantially opaque rear plate 111. In an embodiment, the rear plate 111 may form at least a portion of the second surface 100B. In an embodiment, the rear plate 111 may be formed of coated or colored glass, ceramic, polymer, metal (e.g., aluminum, stainless steel (STS), or magnesium), or a combination of at least two of the above materials.

The electronic device 100 according to an embodiment may include a lateral surface bezel structure (or a lateral surface member) 118 (e.g., a sidewall 141 of the frame structure 140 of FIG. 2). In an embodiment, the lateral surface bezel structure 118 may be combined with the front plate 102 and/or the rear plate 111 to form at least a portion of the third surface 100C of the electronic device 100. For example, the lateral surface bezel structure 118 may form the entire third surface 100C of the electronic device 100. In an embodiment, the lateral surface bezel structure 118 may form the third surface 100C of the electronic device 100 together with the front plate 102 and/or the rear plate 111.

In an embodiment, when the third surface 100C of the electronic device 100 is partially formed by the front plate 102 and/or the rear plate 111, the front plate 102 and/or the rear plate 111 may include a region that is bent at its edge toward the rear plate 111 and/or the front plate 102 and seamlessly extends. For example, the extended region of the front plate 102 and/or the rear plate 111 may be positioned at both ends of a long edge of the electronic device 100, but embodiments of the disclosure are not limited to the above-described example.

In an embodiment, the lateral surface bezel structure 118 may include a metal and/or a polymer. In an embodiment, the rear plate 111 and the lateral surface bezel structure 118 may be integrally formed and may include the same material (e.g., a metallic material such as aluminum), but embodiments of the disclosure are not limited thereto. For example, the rear plate 111 and the lateral surface bezel structure 118 may be formed in separate configurations and/or may include different materials.

In an embodiment, the electronic device 100 may include at least one of a display 101, audio modules 103, 104 and 107, a sensor module, camera modules 105, 112, and 113, a key input device 117, a light emitting element, and/or a connector hole. In an embodiment, the electronic device 100 may omit at least one of the above components (e.g., key input device 117 or light emitting device), or may additionally include other components.

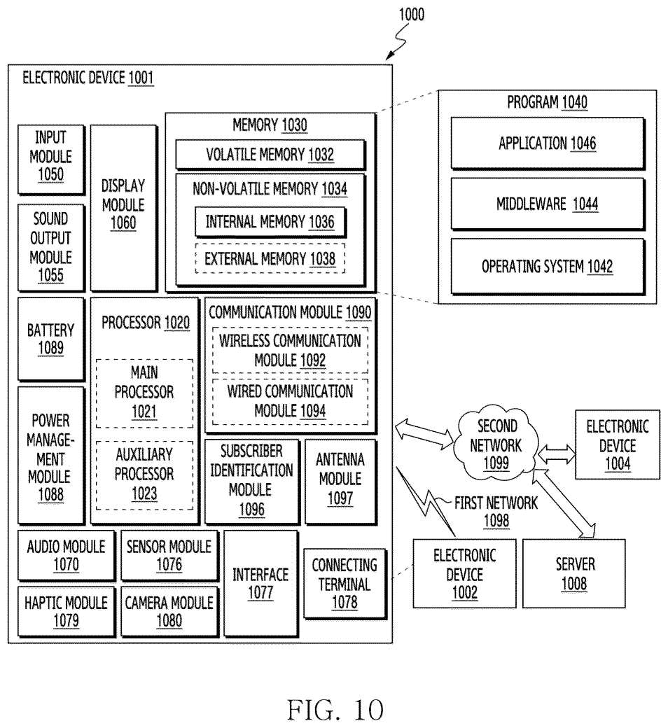

In an embodiment, the display 101 (e.g., the display module 1060 of FIG. 10) may be visually exposed through a significant portion of the front plate 102. For example, at least a portion of the display 101 may be visible through the front plate 102, which forms the first surface 100A. In an embodiment, the display 101 may be disposed on a rear surface of the front plate 102.

In an embodiment, an outer shape of the display 101 may be formed substantially the same as an outer shape of the front plate 102 adjacent to the display 101. In an embodiment, in order to expand an area in which the display 101 is visually exposed, an interval between an outer periphery of the display 101 and an outer periphery of the front plate 102 may be formed substantially the same.

In an embodiment, the display 101 (or the first surface 100A of the electronic device 100) may include a screen display region 101A. In an embodiment, the display 101 may provide visual information to the user through the screen display region 101A. In the illustrated embodiment, when the first surface 100A is viewed from the front, it is illustrated that the screen display region 101A is spaced apart from the outside of the first surface 100A and is positioned inside the first surface 100A, but embodiments of the disclosure are not limited thereto. In an embodiment, when the first surface 100A is viewed from the front, at least a portion of a periphery of the screen display region 101A may substantially coincide with a periphery of the first surface 100A (or the front plate 102).

In an embodiment, the screen display region 101A may include a sensing region 101B configured to obtain the user's biometric information. Herein, the meaning of “the screen display region 101A includes the sensing region 101B” may be understood as at least a portion of the sensing region 101B capable of being overlapped with the screen display region 101A. For example, the sensing region 101B may mean a region capable of displaying visual information by the display 101, like other regions of the screen display region 101A, and additionally obtaining the user's biometric information (e.g., fingerprint). In an embodiment, the sensing region 101B may be formed in the key input device 117.

In an embodiment, the display 101 may include a region in which a first camera module 105 (e.g., the camera module 1080 of FIG. 10) is positioned. In an embodiment, an opening is formed in the region of the display 101, and the first camera module 105 (e.g., a punch hole camera) may be at least partially disposed in the opening to face the first surface 100A. For example, the screen display region 101A may surround at least a portion of a periphery of the opening. In an embodiment, the first camera module 105 (e.g., an under display camera (UDC)) may be disposed below the display 101 to overlap the region of the display 101. For example, the display 101 may provide visual information to the user through the region, and additionally, the first camera module 105 may obtain an image corresponding to a direction facing the first surface 100A through the region of the display 101.

In an embodiment, the display 101 may be combined with or disposed adjacent to a touch sensing circuit, a pressure sensor capable of measuring touch intensity (pressure), and/or a digitizer detecting a magnetic field type stylus pen.

In an embodiment, the audio modules 103, 104, and 107 (e.g., the audio module 1070 of FIG. 10) may include microphone holes 103 and 104 and a speaker hole 107.

In an embodiment, the microphone holes 103 and 104 may include a first microphone hole 103 formed in a partial region of the third surface 100C and a second microphone hole 104 formed in a partial region of the second surface 100B. A microphone for obtaining external sound may be disposed inside the microphone holes 103 and 104. The microphone may include a plurality of microphones to detect a direction of sound.

In an embodiment, the second microphone hole 104 formed in a partial region of the second surface 100B may be disposed adjacent to the camera modules 105, 112, and 113. The second microphone hole 104 may obtain sound according to an operation of the camera modules 105, 112, and 113. However, embodiments of the disclosure are not limited thereto.

In an embodiment, the speaker hole 107 may include an external speaker hole 107 and a call receiver hole. The external speaker hole 107 may be formed on a portion of the third surface 100C of the electronic device 100. In an embodiment, the external speaker hole 107 and the microphone hole 103 may be implemented as a single hole. In an embodiment, a call receiver hole may be formed on another portion of the third surface 100C. For example, the call receiver hole may be formed on the opposite side of the external speaker hole 107 on the third surface 100C. For example, based on the illustration of FIG. 1, the external speaker hole 107 may be formed on the third surface 100C corresponding to a lower end of the electronic device 100, and the call receiver hole may be formed on the third surface 100C corresponding to au upper end of the electronic device 100. However, embodiments of the disclosure are not limited thereto, and in an embodiment, the call receiver hole may be formed in a position other than the third surface 100C. For example, the call receiver hole may be formed by a separate space between the front plate 102 (or the display 101) and the lateral surface bezel structure 118.

In an embodiment, the electronic device 100 may include at least one speaker configured to output sound to the outside of the housing 110 through the external speaker hole 107 and/or the call receiver hole.

In an embodiment, the sensor module (e.g., the sensor module 1076 of FIG. 10) may generate an electrical signal or a data value corresponding to an operating state inside the electronic device 100 or an external environmental state. For example, the sensor module may include at least one of a proximity sensor, an HRM sensor, a fingerprint sensor, a gesture sensor, a gyro sensor, a barometric sensor, a magnetic sensor, an acceleration sensor, a grip sensor, a color sensor, an infrared (IR) sensor, a biometric sensor, a temperature sensor, a humidity sensor, or an illuminance sensor.

In an embodiment, the camera module 105, 112, and 113 (e.g., the camera module 1080 of FIG. 10) may include a first camera module 105 disposed to face the first surface 100A of the electronic device 100, a second camera module 112 disposed to face the second surface 100B, and a flash 113.

In an embodiment, the second camera module 112 may include a plurality of cameras (e.g., dual cameras, triple cameras, or quad cameras). However, the second camera module 112 is not necessarily limited to including a plurality of cameras, and may include one camera.

In an embodiment, the first camera module 105 and the second camera module 112 may include one or more lenses, an image sensor, and/or an image signal processor.

In an embodiment, the flash 113 may include, for example, a light emitting diode or a xenon lamp. In an embodiment, two or more lenses (infrared camera, wide-angle and telephoto lens) and image sensors may be disposed on a side of the electronic device 100.

In an embodiment, the key input device 117 (e.g., the input module 1050 of FIG. 10) may be disposed on the third surface 100C of the electronic device 100. In an embodiment, the electronic device 100 may not include some or all of the key input devices 117, and the excluded key input device 117 may be implemented in another form, such as a soft key, on the display 101.

In an embodiment, the connector hole may be formed on the third surface 100C of the electronic device 100 to accommodate a connector of an external device. A connection terminal (e.g., the connecting terminal 1078 of FIG. 10) electrically connected to a connector of an external device may be disposed in the connector hole. The electronic device 100 according to an embodiment may include an interface module (e.g., the interface 1077 of FIG. 10) for processing an electrical signal transmitted and received through the connection terminal.

According to an embodiment, the electronic device 100 may include a light emitting element. For example, the light emitting element may be disposed on the first surface 100A of the housing 110. The light emitting element may provide state information of the electronic device 100 in an optical form. In an embodiment, the light emitting element may provide a light source in conjunction with the operation of the first camera module 105. For example, the light emitting element may include an LED, an IR LED, and/or a xenon lamp.

FIG. 2 is an exploded perspective view of an electronic device according to an embodiment.

Hereinafter, an overlapping description of a configuration having the same reference numerals as the above-described configuration will be omitted.

Referring to FIG. 2, the electronic device 100 according to an embodiment may include a frame structure 140, a first printed circuit board 150, a second printed circuit board 152, a cover plate 160, and a battery 170.

In an embodiment, the frame structure 140 may include a sidewall 141 forming an exterior (e.g., the third surface 100C of FIG. 1) of the electronic device 100 and a support portion 143 extending inward from the sidewall 141. In an embodiment, the frame structure 140 may be disposed between the display 120 and the rear plate 111. In an embodiment, the sidewall 141 of the frame structure 140 may surround a space between the rear plate 111 and the front plate 102 (and/or the display 120), and the support portion 143 of the frame structure 140 may extend from the sidewall 141 within the space. According to an embodiment, the sidewall 141 forming the lateral surface (e.g., the third surface 100C of FIG. 1) of the electronic device 100 may include the speaker hole 107 connecting the inside and the outside of the electronic device 100. The speaker hole 107 may penetrate the sidewall 141.

In an embodiment, the frame structure 140 may support or accommodate other components included in the electronic device 100. For example, the display 101 may be disposed on a surface of the frame structure 140 facing a direction (e.g., +z direction), and the display 101 may be supported by the support portion 143 of the frame structure 140. In an embodiment, the first printed circuit board 150, the second printed circuit board 152, the battery 170, and the second camera module 112 may be disposed on another surface of the frame structure 140 facing a direction (e.g., the −z direction) opposite to the direction. The first printed circuit board 150, the second printed circuit board 152, the battery 170, and the second camera module 112 may be respectively seated in recesses defined by the sidewall 141 and/or the support portion 143 of the frame structure 140.

In an embodiment, the first printed circuit board 150, the second printed circuit board 152, and the battery 170 may be coupled to the frame structure 140, respectively. For example, the first printed circuit board 150 and the second printed circuit board 152 may be fixedly disposed on the frame structure 140 through a coupling member such as a screw. For example, the battery 170 may be fixedly disposed on the frame structure 140 through an adhesive member (e.g., a double-sided tape). However, embodiments of the disclosure are not limited to the above-described example.

In an embodiment, the cover plate 160 may be disposed between the first printed circuit board 150 and the rear plate 111. In an embodiment, the cover plate 160 may be disposed on the first printed circuit board 150. For example, the cover plate 160 may be disposed on a surface facing the −z direction of the first printed circuit board 150.

In an embodiment, the cover plate 160 may at least partially overlap the first printed circuit board 150 with respect to the z-axis. In an embodiment, the cover plate 160 may cover at least a portion of the first printed circuit board 150. Accordingly, the cover plate 160 may protect the first printed circuit board 150 from a physical impact or prevent the connector coupled to the first printed circuit board 150 from being separated.

In an embodiment, the cover plate 160 may be fixedly disposed on the first printed circuit board 150 through a coupling member (e.g., a screw), or may be coupled to the frame structure 140 together with the first printed circuit board 150 through the coupling member.

In an embodiment, the display 101 may be disposed between the frame structure 140 and the front plate 102. For example, the front plate 102 may be disposed on a side (e.g., in +z direction) of the display 101, and a frame structure 140 may be disposed on another side (e.g., in-z direction).

In an embodiment, the front plate 102 may be coupled to the display 101. For example, the front plate 102 and the display 101 may be attached to each other through an optical adhesive member (e.g., optically clear adhesive (OCA) or optically clear resin (OCR)) interposed between the front plate 102 and the display 101.

In an embodiment, the front plate 102 may be coupled to the frame structure 140. For example, the front plate 102 may include an outer portion extending outside the display 101 when viewed in the z-axis direction, and may be attached to the frame structure 140 through an adhesive member (e.g., double-sided tape) disposed between the outer portion of the front plate 102 and the frame structure 140 (e.g., the sidewall 141). However, embodiments of the disclosure are not limited to the above-described example.

In an embodiment, the first printed circuit board 150 and/or the second printed circuit board 152 may be equipped with a processor (e.g., the processor 1020 of FIG. 10), memory (e.g., the memory 1030 of FIG. 10), and/or an interface (e.g., the interface 1077 of FIG. 10). The processor may include, for example, one or more of a central processing unit, an application processor, a graphic processing unit, an image signal processor, a sensor hub processor, or a communication processor. The memory may include, for example, volatile memory or non-volatile memory. The interface may include, for example, a high definition multimedia interface (HDMI), a universal serial bus (USB) interface, an SD card interface, and/or an audio interface. The interface may electrically or physically connect the electronic device 100 to an external electronic device, and may include a USB connector, an SD card/MMC connector, or an audio connector. In an embodiment, the first printed circuit board 150 and the second printed circuit board 152 may be operably or electrically connected to each other via a connection member (e.g., a flexible printed circuit board).

In an embodiment, the battery 170 (e.g., the battery 1089 of FIG. 10) may supply power to at least one component of the electronic device 100. For example, the battery 170 may include a rechargeable secondary battery or a fuel cell. At least a portion of the battery 170 may be disposed on substantially the same plane as the first printed circuit board 150 and/or the second printed circuit board 152.

The electronic device 100 according to an embodiment may include an antenna module (e.g., the antenna module 1097 of FIG. 10). In an embodiment, the antenna module may be disposed between the rear plate 111 and the battery 170. The antenna module may include, for example, a near field communication (NFC) antenna, a wireless charging antenna, and/or a magnetic secure transmission (MST) antenna. The antenna module may, for example, perform short-range communication with an external device or wirelessly transmit and receive power with an external device.

In an embodiment, the housing 110 of the electronic device 100 may mean a configuration or structure forming at least a portion of the exterior of the electronic device 100. In this regard, at least a portion of the front plate 102, the frame structure 140, and/or the rear plate 111, which form the exterior of the electronic device 100, may be referred to as the housing 110 of the electronic device 100.

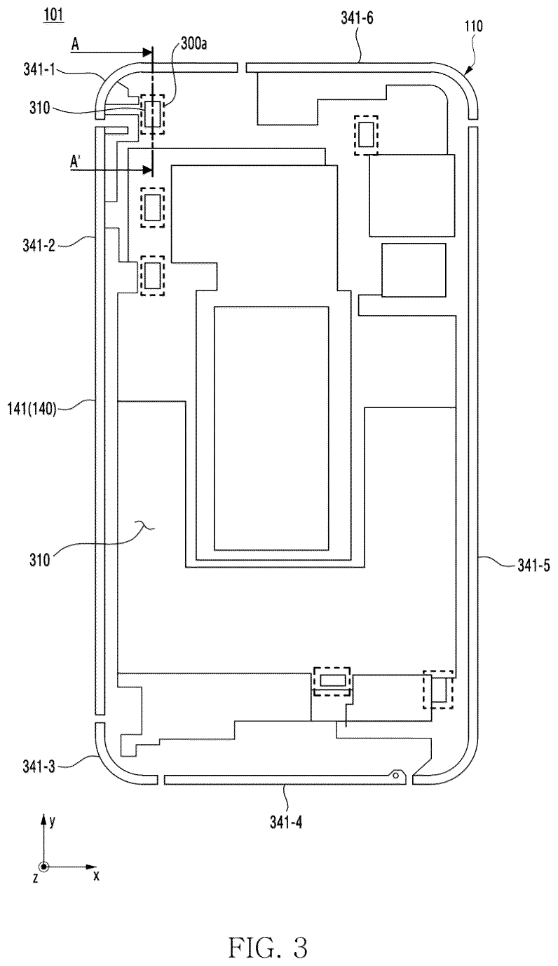

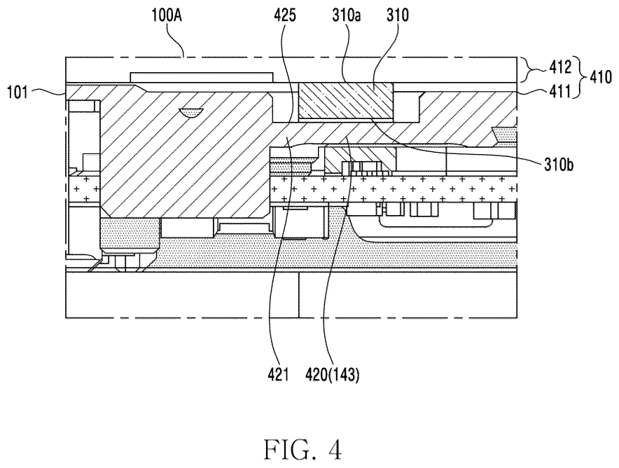

FIG. 3 is a plan view illustrating a bracket of an electronic device according to an embodiment. FIG. 4 is a cross-sectional view of an electronic device in which a portion where a conductive connector connecting a display and a bracket is disposed is cut, according to an embodiment.

Referring to FIGS. 3 and 4, the electronic device 100 may include a display 410 (e.g., the display 101 of FIG. 1), a bracket 420 (e.g., the support portion 143 of FIG. 2), and a conductive connector 310.

The display 410 may define at least a portion of the front surface 100A of the electronic device 100. For example, the display 410 may be or correspond to at least a portion of the exterior of the electronic device 100 (or at least a portion of the exterior of the housing 110). The display 410 may be supported by the bracket 420 (or the housing 110, or the support portion 143). The display 410 may be disposed on the sidewall 141 of the lateral surface bezel structure 118 of the housing 110.

The display 410 may include a plurality of layers 411 and 412. Among the plurality of layers 411 and 412, a conductive layer 411 facing the inside of the electronic device 100 (or an inner space of the housing 110) may be formed of a metallic material. The conductive layer 411 may be positioned on a rear surface of the display 410 to improve a screen quality of the display 410. The remaining portion of the plurality of layers 412 may be disposed on the conductive layer 411. The conductive layer 411 may be formed from a metal material. For example, the metal material may include copper or stainless steel. The remaining portion of the plurality of layers 412 may include a display panel for driving the display 410. For example, the plurality of layers 412 may include layers that function as at least one of a transparent member, a polarizer, a color filter, a pixel layer, a touch panel (or a touch pattern), a digitizer, or a thin film transistor. The plurality of layers 412 may be attached to each other by an adhesive or an adhesive layer. In an embodiment, the conductive layer 411 may be formed separately from the display 410 and may be positioned on a rear surface of the display 410. For example, the conductive layer 411 may be disposed to support the rear surface of the display 410 as a display support member (e.g., a lattice plate).

The transparent member among the plurality of layers 412 may be a cover glass or a window. The window may define at least a portion of the housing 110 or the front surface 100A of the electronic device 100. The polarizer may reduce the amount of light reflected in the display 410 after being incident from the outside of the electronic device 100. As the amount of light reflected in the display 410 is reduced by the polarizer, visibility of the display 410 may be improved. To improve visibility, the display 410 may include a color filter, instead of the polarizer. However, embodiments of the disclosure are not limited thereto, and the display 410 may include both the polarizer and the color filter. The pixel layer may be configured to provide visual information to the outside. The pixel layer may be configured to emit light of a specified color from each pixel to the outside. The pixel layer may be configured to operate by a thin film transistor. The touch panel or the digitizer may be configured to receive an external input transmitted through an outer surface of the display 410.

The bracket 420 may be disposed in an inner space defined by the housing 110. The bracket 420 may be a portion of the housing 110. For example, the housing 110 may include a bracket 420 extending from the sidewall 141 toward the inner space.

The bracket 420 may be formed from a metal material (or a conductive material) to have rigidity to form a frame inside the electronic device 100. For example, the bracket 420 may include a conductive portion 421. However, embodiments of the disclosure are not limited thereto, and the bracket 420 may further include a non-conductive portion. The non-conductive portion may be formed from a polymer or an injection material for light weight of the electronic device 100 or a function of the electronic device 100.

The conductive portion 421 of the bracket 420 may include a recess portion 425 recessed from a surface facing the display 410. The bracket 420 may be disposed toward the display 410 and may support the display 410 by being in direct contact with it or in contact through other components.

The conductive connector 310 may be disposed between the conductive layer 411 of the display 410 and the conductive portion 421 of the bracket 420. For example, the conductive connector 310 may be interposed between the bracket 420 and the display 410. The recess portion 425 of the bracket 420 may be a portion of the conductive portion 421 of the bracket 420. The recess portion 425 of the bracket 420 may accommodate a portion of the conductive connector 310. The conductive connector 310 may be disposed on the recess portion 425. For example, the recess portion 425 may support the conductive connector 310. The conductive connector 310 (disposed in the recess portion 425) may support the display 410 by contacting the conductive layer 411 of the display 410.

According to an embodiment, as shown in FIG. 3, the housing 110 may include one or more conductive portions 341-1, 341-2, 341-3, 341-4, 341-5, and 341-6 that function as an antenna (e.g., the antenna module 1097 of FIG. 10) for communication with an external electronic device (e.g., the electronic device 1002 of FIG. 10). For example, the one or more conductive portions 341-1, 341-2, 341-3, 341-4, 341-5, and 341-6 may form at least a portion of the sidewall 141 (or the lateral surface bezel structure 118) of the housing 110. For example, the bracket 420 may be combined with the sidewall 141 including the one or more conductive portions 341-1, 341-2, 341-3, 341-4, 341-5, and 341-6, or may be integrally formed with the sidewall 141. The display 410 and the bracket 420 may be configured to function as a ground, in order to improve performance of a signal received by the electronic device 100 from the external electronic device 1002 and/or a server (e.g., the server 1008 of FIG. 10) and/or a signal transmitted from the electronic device 100 to the external electronic device 1002 and/or the server 1008, via the one or more conductive portions 341-1, 341-2, 341-3, 341-4, 341-5, and 341-6 that function as an antenna.

For example, the conductive layer 411 of the display 410 may be electrically connected to the conductive portion 421 of the bracket 420 through the conductive connector 310 that is connected to the conductive layer 411 of the display 410 and the conductive portion 421 of the bracket 420. For example, the conductive layer 411 of the display 410 that is in contact with a surface 310a of the conductive connector 310 may be electrically connected to the bracket 420 that is in contact with another surface 310b of the conductive connector 310 of the conductive connector 310 through the conductive connector 310, the other surface 310b opposite to the surface 310a. The conductive connector 310 may provide (or may include) a current path between the conductive portion 421 of the bracket 420 and the conductive layer 411 of the display 410. The other surface 310b of the conductive connector 310 may be attached to the recess portion 425 (or the conductive portion 421 of the bracket 420). The conductive connector 310 may be attached to the recess portion 425 and the conductive layer 411 of the display 410.

The conductive connector 310 may have elasticity. For example, the conductive connector 310 may be pressed by the bracket 420 and the display 410 when the electronic device 100 is assembled. The conductive connector 310 may be compressed by the pressure. Since the conductive connector 310 is pressed by the display 410 and the bracket 420 within the assembled electronic device 100, the conductive connector 310 may press the display 410 in a direction toward the outside of the electronic device 100 or press the bracket 420 in a direction toward a rear surface of the electronic device 100 by repulsive force (or restoring force) of the conductive connector 310. The conductive connector 310 having elasticity may be configured to maintain contact between the bracket 420 and the conductive layer 411 of the display 410. The conductive connector 310 pressing between the bracket 420 and the display 410 by elasticity may reduce electrical resistance between the conductive portion of the bracket 420 and the conductive layer 411 of the display 410. For example, because the conductive connector 310 loosely inserted between the bracket 420 and the display 410 has a relatively small contact area between the bracket 420 and the display 410, the resistance between the conductive layer 411 of the display 410 and the conductive portion 421 of the bracket 420 may increase. Since the conductive connector 310 (in close contact with the bracket 420 and the display 410) has a relatively large contact area between the bracket 420 and the display 410, the resistance between the conductive layer 411 of the display 410 and the conductive portion 421 of the bracket 420 may be reduced. When the resistance between the conductive layer 411 of the display 410 and the conductive portion 421 of the bracket 420 is reduced, a current flow according to an electrical connection between the conductive layer 411 of the display 410 and the conductive portion 421 of the bracket 420 may be improved, so the electronic device 100 may provide an effect of increasing a conductive portion operated as a ground.

For example, FIG. 3 illustrates that the electronic device 100 includes one conductive connector 310. However, embodiments of the disclosure are not limited thereto. For example, the electronic device 100 may include a plurality of conductive members that provide a current path between the conductive portion 421 of the bracket 420 and the conductive layer 411 of the display 410. The plurality of conductive members may be disposed adjacent to one or more conductive portions of the sidewall 141 or the bracket 420 functioning as an antenna.

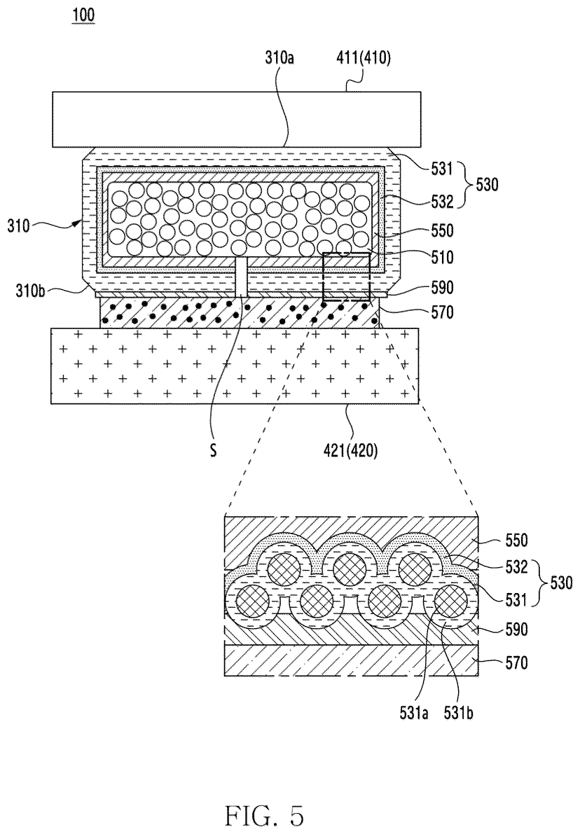

In the electronic device 100, a material (e.g., an adhesive material) that oxidizes the bracket 420 or the conductive connector 310 may leak from the conductive connector 310 by pressure for contact between the bracket 420 and the conductive connector 310. A structure for reducing the oxidation of the conductive connector 310 and increasing a conductive portion operated as a ground for an antenna may be required. A structure of the conductive connector 310 is described below, with respect to FIG. 5.

According to one or more embodiments described above, the electronic device 100 may include the conductive connector 310 that provides (or includes) a current path by electrically connecting the conductive layer 411 and the bracket 420 of the display 410. The conductive connector 310 may increase a conductive portion operating as a ground of the electronic device 100 by forming the current path.

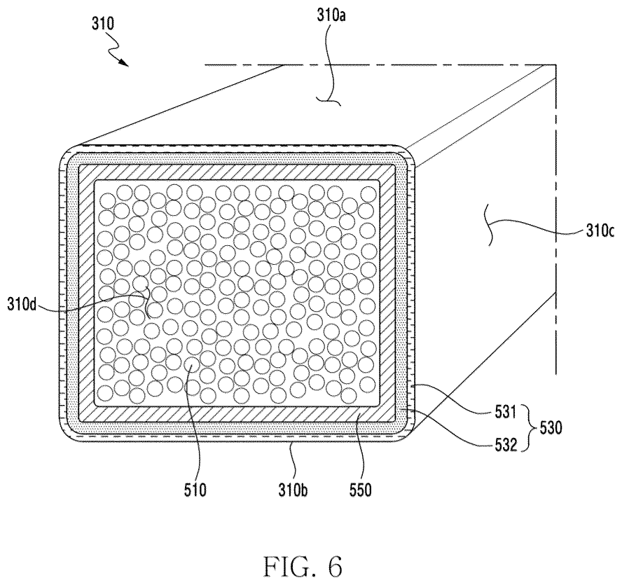

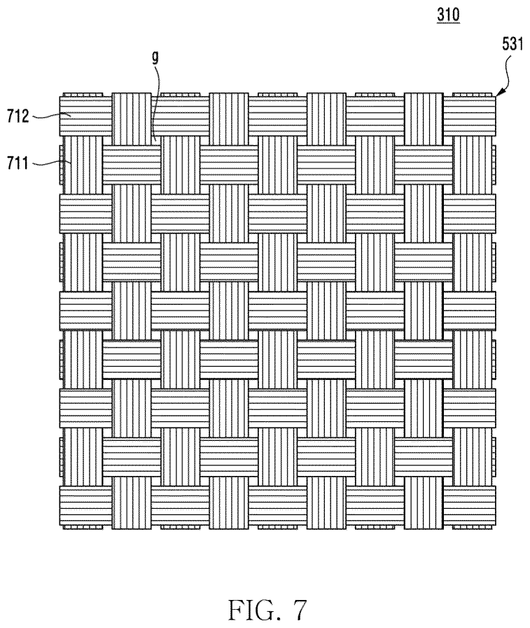

FIG. 5 is an enlarged cross-sectional view a periphery of a conductive connector. FIG. 6 is a perspective view of an example conductive connector. FIG. 7 is a plan view of an example conductive connector.

Referring to FIGS. 5, 6, and 7, the electronic device 100 may include a display 410, a conductive connector 310, and a bracket 420. The display 410 may include a conductive layer 411. The bracket 420 may include a conductive portion 421. The conductive connector 310 may be disposed between the conductive layer 411 of the display 410 and the conductive portion 421 of the bracket 420. The conductive connector 310 may be in contact with the conductive layer 411 of the display 410 and the conductive portion 421 of the bracket 420. The conductive connector 310, in which an outer surface formed of a conductive material contacts the conductive layer 411 of the display 410 and the conductive portion 421 of the bracket 420, may electrically connect the conductive layer 411 of the display 410 and the conductive portion 421 of the bracket 420. The conductive connector 310 may be pressed by the display 410 and the bracket 420 for a stable electrical connection between the display 410 and the bracket 420. The conductive connector 310 may be in close contact with the conductive layer 411 of the display 410 and the conductive portion 421 of the bracket 420 by the pressure. As the conductive connector 310 is in close contact with the conductive layer 411 of the display 410 and the conductive portion 421 of the bracket 420, the electrical resistance between the conductive layer 411 of the display 410 and the conductive portion 421 of the bracket 420 may be reduced.

In some embodiments, the conductive connector 310 may include an interior part 510, an exterior part 530, and an adhesive 550.

The interior part 510 may form (or may include) the inside of the conductive connector 310. The interior part 510 may include an elastic foam. The interior part 510 formed of the elastic foam may be deformed by external force. For example, when the electronic device 100 is assembled, the interior part 510 may be compressed by the display 410 and the bracket 420. The elastic foam of the interior part 510 may be formed from a polyurethane (PU). For example, the elastic from may comprise a PU.

The exterior part 530 may include a coating 532 and a conductive outer jacket 531. The coating 532 may form an inner surface of the exterior part 530. The coating 532 may be referred to as an inner portion of the exterior part 530, in terms of forming the inner surface of the exterior part 530. The conductive outer jacket 531 may form an outer surface of the exterior part 530. The conductive outer jacket 531 may be referred to as an ‘outer portion’ in terms of forming the outside of the exterior part 530.

The conductive connector 310 may have a hexahedron shape. For example, a surface 310a of the conductive connector 310 may contact the display 410. The surface 310a of the conductive connector 310 may be referred to as an upper surface. Another surface 310b opposite to the surface 310a of the conductive connector 310 may face the conductive portion 421 of the bracket 420. The other surface 310b of the conductive connector may be referred to as a lower surface. The conductive connector 310 may include lateral surfaces 310c and 310d connecting the surface 310a and the other surface 310b.

The exterior part 530 may be disposed on two lateral surfaces 310c spaced apart from each other from among the surface 310a of the conductive connector 310 facing the conductive layer 411 of the display 410, the other surface 310b facing the conductive portion 421 of the bracket 420, and the four lateral surfaces 310c and 310d between the surface 310a and the other surface 310b. The interior part 510 (made of the elastic foam) may be exposed from the (remaining) two lateral surfaces 310d from among the four lateral surfaces 310c and 310d of the conductive connector 310.

The conductive outer jacket 531 may include a conductive warp 711 and a conductive weft 712. The conductive outer jacket 531 may be woven by the conductive warp 711 and the conductive weft 712. The outer portion of the exterior part 530, including the conductive outer jacket 531, may include at least one non-conductive portion formed from an elastic material (e.g., PU) positioned within one or more gaps “g” defined by the conductive warp 711 and the conductive weft 712. The non-conductive portion may include the same material as the coating 532. For example, the non-conductive portion may be a portion of the coating 532. The non-conductive portion may be connected to or coupled to the coating 532. The non-conductive portion may be a portion of the coating 532. The coating 532 may include the same elastic material (e.g., PU) as the elastic foam. The inner portion (e.g., the coating 532) of the exterior part 530 may be connected to the non-conductive portion of the outer portion of the exterior part 530. For example, a portion of the coating 532 may at least partially fill the gaps “g” (or groove portions) formed on an outer surface of the conductive outer jacket 531 (or conductive woven fabric). The gaps “g” may be formed by being woven by the conductive warp 711 and the conductive weft 712. The gaps “g” of the conductive outer jacket 531 may be connected to each other, and may extend from a surface of the conductive outer jacket 531 to another surface of the conductive outer jacket 531. The gaps “g” of the conductive outer jacket 531 may indicate a path or a hole connecting the outer surface and the inner surface of the conductive outer jacket 531. The conductive outer jacket 531 may be indicated as a conductive woven fabric in terms of the conductive warp 711 and the conductive weft 712 being woven.

The conductive warp 711 and the conductive weft 712 forming the conductive outer jacket 531 may be indicated by a conductive fiber. Each of the conductive warp 711 and the conductive weft 712 may include a fiber 531a and a conductive coating 531b. In an embodiment, at least one of the conductive warp 711 or the conductive weft 712 may include a fiber 531a and a conductive coating 531b. The fiber 531a may indicate a core of the conductive warp 711 and the conductive weft 712. The fiber 531a may include a polymer material and may be thin and flexible. The conductive coating 531b may laterally surround the fiber 531a. The conductive coating 531b may be coated along the outer surface of the fiber 531a. The conductive coating 531b may be plated on the outer surface of the fiber 531a. The conductive coating 531b may include Ni, Cu, Au, and/or Ag. For example, the conductive coating 531b may be plated or coated on the outer surface of the fiber 531a with Ni, Cu, Au, and/or Ag.

As the conductive warp 711 and the conductive weft 712 (including the conductive coating 531b disposed along the outer surface of the fiber 531a) are woven, conductive coatings of the conductive warp 711 and the conductive weft 712 may contact each other. The conductive coatings of the conductive warp 711 and the conductive weft 712 may provide (or may become) an outer surface of the conductive connector 310 having conductivity. The conductive connector 310 having conductivity may electrically connect the conductive layer 411 of the display 410 and the conductive portion 421 of the bracket 420. The conductive connector 310 may provide (or may include) a conductive path between the conductive layer 411 of the display 410 and the conductive portion 421 of the bracket 420. For example, the conductive layer 411 of the display 410 and the conductive portion 421 of the bracket 420 connected by the conductive warp 711 and the conductive weft 712 of the conductive connector 310 may be configured to function as a ground.

The interior part 510 and the exterior part 530 may be coupled by an adhesive 550. The adhesive 550 may be placed between the interior part 510 and the exterior part 530. The adhesive 550 may be in contact with inner portions of the interior part 510 and the exterior part 530. For example, the adhesive 550 may be in contact with the outer surface of the elastic foam of the interior part 510, and the adhesive 550 may be in contact with the coating 532 of the exterior part 530.

In the case that the coating 532 is omitted in the conductive connector 310, the adhesive 550 in contact with the inner surface of the exterior part 530 may flow out of the conductive connector 310 through the gap “g” formed in the conductive outer jacket 531 of the exterior part 530. The conductive outer jacket 531 of the exterior part 530 may be woven by the conductive warp 711 and the conductive weft 712, and may include a gap “g” positioned between the conductive warp 711 and the conductive weft 712. There may be a plurality of gaps. The plurality of gaps may be connected to each other to connect a surface of the conductive outer jacket 531 and another surface. For example, a gap formed on the surface of the conductive outer jacket 531 may be connected to a gap disposed on the other surface of the conductive outer jacket 531. In an embodiment, a portion of the gaps may penetrate the conductive outer jacket 531 to connect the surface of the conductive outer jacket 531 to the other surface. The adhesive 550 may leak to the outer surface of the conductive connector 310 through a gap (or gaps) providing a passage connecting the two surfaces of the conductive outer jacket 531. The coating 532 may reduce the transfer of the adhesive 550 to the conductive outer jacket 531 by filling a portion of the gap “g” formed in the conductive outer jacket 531.

The adhesive 550 may include acrylic oligomer, acrylic copolymer, tackifier, or a combination of these example adhesive components. The adhesive 550 may include a carboxyl group (—COOH) to increase adhesive strength. The carboxyl group is not bound to a polymer structure of the adhesive 550 at high temperature or high pressure, and may move freely between the polymer structures. When assembling the electronic device 100 (e.g., when assembling the display 410 and the housing 110), if the conductive connector 310 is pressed or if the conductive layer 411 of the display 410 or the conductive portion 421 of the bracket 420 is pressed by the restoring force of the conductive connector 310, the carboxyl group in the adhesive 550 may leak to the outside of the conductive connector 310. The carboxyl group leaked to the outside of the conductive connector 310 has acidity and may increase reactivity with surrounding metals. As the reactivity increases, an oxide film may be formed on an outer surface of a metal in contact with the carboxyl group. For example, since the conductive layer 411 of the display 410 in contact with the conductive connector 310, the conductive portion 421 of the bracket 420 in contact with the conductive connector 310, or the outer surface of the conductive connector 310 is oxidized by the carboxyl group leaked from the adhesive 550, an oxide film may be formed. Due to the oxide film, the resistance of an outer surface of a counterpart in contact with the conductive connector 310 may increase, thereby impeding a flow of current or blocking a portion of an electrical path.

In order to improve an electrical connection between the conductive layer 411 of the display 410 and the conductive portion 421 of the bracket 420 by the conductive connector 310 the conductive connector 310 may further include the coating 532 to reduce a leakage of the carboxyl group to the outside. For example, the coating 532 may be configured to limit the adhesive 550 from flowing toward the display 410 or the conductive adhesive 570 through one or more gaps of the exterior part 530. The coating 532 may fill a portion of a gap of the inner surface of the conductive outer jacket 531. For example, the coating 532 may be disposed on the inner surface of the conductive outer jacket 531 and may be introduced into a portion of the gap “g” by being thermocompression bonded. The thermocompression bonded coating 532 may be attached to the conductive outer jacket 531. The coating 532 may at least partially fill a gap in contact with the coating 532 from among gaps disposed in the conductive outer jacket 531. For example, a portion of the coating 532 (or a non-conductive portion disposed on the outer portion of the exterior part 530) may at least partially fill a gap positioned at a boundary of the outer portion of the exterior part 530, which contacts the inner portion of the exterior part 530 from among the one or more gaps. As a portion of the gap “g” is filled by the coating 532, the adhesive 550 may be limited from moving through the gap “g” to the outside of the conductive connector 310.

The coating 532 may be formed of an elastic material, thereby maintaining a restoration speed and low resistance of the conductive connector 310. The coating 532 may reduce the leakage of the adhesive 550 through the gaps “g” of the conductive outer jacket 531 even under high heat and pressure during the assembly process. The coating 532 may reduce the leakage of low-molecular-weight components (e.g., carboxyl group (COOH)) of the adhesive 550, thereby reducing the oxidation of the outer surface of the conductive outer jacket 531 or the conductive connector 310 and minimizing the delamination of the plating layer of the conductive outer jacket 531.

The electronic device 100 may further include a conductive adhesive 570. The conductive adhesive 570 may attach the conductive connector 310 to the conductive portion 421 of the bracket 420. For example, the conductive adhesive 570 may fill a portion of one or more gaps “g” positioned on the outer surface of the exterior part 530. A portion of gaps, which is filled with the conductive adhesive 570 from among the one or more gaps “g”, may face the conductive portion 421 of the bracket 420.

Another portion of gaps, which is positioned on the outer surface of the exterior part 530 from among the one or more gaps “g”, may be empty. For example, the conductive adhesive 570 may be disposed on a surface facing the bracket 420 from among the outer surface of the exterior part 530. The conductive portion 421 of the bracket 420 may be attached through the conductive adhesive 570 disposed on a surface 310b facing the bracket 420 from among the outer surface of the exterior part 530. The conductive portion 421 of the bracket 420 may be electrically connected to the conductive connector 310 through the conductive adhesive 570.

The conductive adhesive 570 may be attached to the conductive connector 310 by being in contact with the other surface 310b of the conductive connector 310. The conductive adhesive 570 may be attached to the conductive portion 421 of the bracket 420 by being in contact with the conductive portion 421. The conductive adhesive 570 may electrically connect the bracket 420 and the conductive connector 310. The conductive adhesive 570 can include conductive particles. As the conductive adhesive 570 is pressed, the conductive particles may be in contact with each other. The conductive particles in contact with each other may electrically connect the conductive portion 421 of the bracket 420 and the conductive connector 310. The conductive portion 421 of the bracket 420 may be electrically connected to the conductive layer 411 of the display 410, through the conductive particles in contact with each other.

The conductive connector 310 may further include a conductive layer 590. The conductive layer 590 included in the conductive connector 310 may define another surface 310b of the conductive connector 310. The other surface 310b of the conductive connector 310 may indicate a surface facing the conductive portion 421 of the bracket 420. For example, the conductive layer 590 of the conductive connector 310 may be disposed on a surface of the exterior part 530 facing the conductive portion 421 of the bracket 420 of the conductive connector 310. The conductive layer 590 of the conductive connector 310 may include Au or Ag. For example, the conductive layer 590 of the conductive connector 310 may be plated or deposited with Ni, Cu, Au, and/or Ag on a surface of the exterior part 530 of the conductive connector 310. The surface of the exterior part 530 on which a metal material is plated or deposited may be in contact with the conductive adhesive 570 disposed on the conductive portion 421. For example, the surface of the exterior part 530 may be attached to the conductive adhesive 570. The conductive layer 590 of the conductive connector 310 may form a boundary surface between the conductive connector 310 and the conductive adhesive 570. The conductive layer 590 of the conductive connector 310 formed from Au or Ag may provide resistance of chemical reactions by a material (e.g., a carboxyl group) included in the conductive adhesive. For example, the conductive layer 590 of the conductive connector 310, formed from Au or Ag, may reduce the oxidation caused by the adhesive material of the conductive adhesive 570. Since oxidation is suppressed on a surface formed from the conductive layer 590 in contact with the conductive adhesive 570 from among the outer surfaces of the conductive connector 310, the conductive connector 310 may provide a stable electrical connection with the conductive portion 421 of the bracket 420 attached to the conductive adhesive 570. For example, the conductive connector 310 may improve resistance stability by suppressing the oxidation of the surface of the exterior part 530 of the conductive connector 310.

According to an embodiment, a thickness of components of the conductive connector 310 may be as follows. A thickness of the interior part 510 (or elastic foam) may be (about) 400 micrometers to (about) 600 micrometers. A thickness of the adhesive 550 may be (about) 5 micrometers to (about) 10 micrometers. A thickness of the coating 532 may be (about) 3 micrometers to (about) 5 micrometers. A thickness of the conductive outer jacket 531 may be (about) 20 micrometers to (about) 25 micrometers. A thickness of the conductive adhesive 570 may be (about) 5 micrometers to (about) 12 micrometers.

In the above embodiment, the conductive outer jacket 531 is woven by a plurality of conductive fibers, but embodiments of the disclosure are not limited thereto. According to an embodiment, the conductive outer jacket 531 may have a rough outer surface. The conductive outer jacket 531 with a rough outer surface may increase a contact area with the adhesive and improve the adhesive strength.

The electronic device 100 according to the above-described embodiment may electrically connect components (e.g., the conductive layer 411 of the display 410 and the conductive portion 421 of the bracket 420) having conductivity through the conductive connector 310. The electrically connected conductive components may improve the ground performance of the electronic device and may improve the radiation performance of an antenna by improving the shielding of noise. The coating 532 disposed in the conductive connector 310 may reduce the oxidation of an outer surface of the conductive connector 310 due to a leakage of the carboxyl group of the adhesive according to the pressure of the conductive connector 310. By preventing the oxidation of the conductive connector 310, a stability of an electrical connection between the conductive layer 411 of the display 410 and the conductive portion 421 of the bracket 420 may be increased.

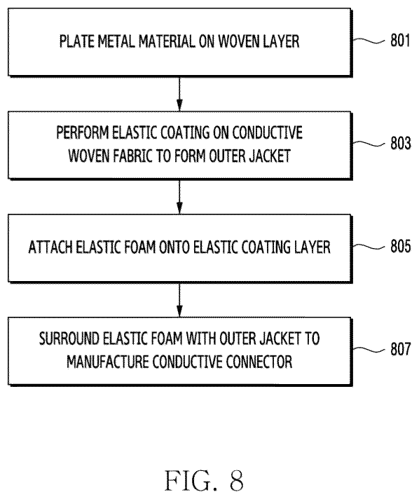

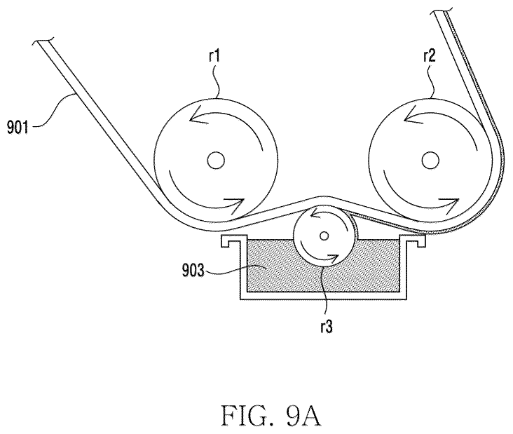

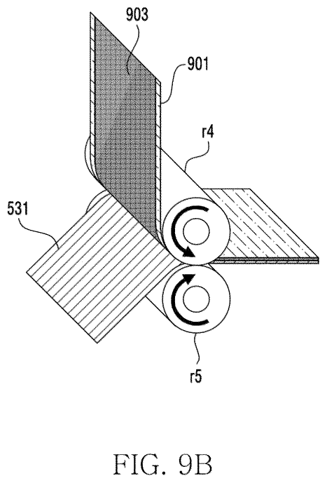

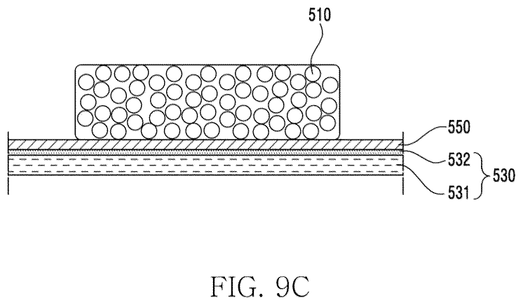

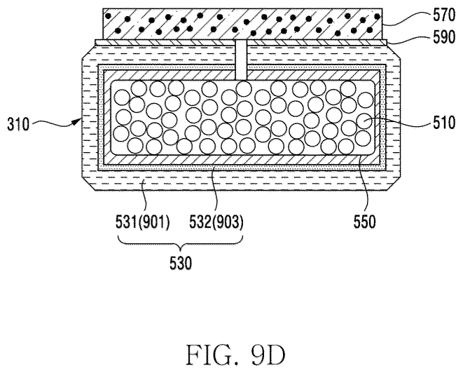

FIG. 8 illustrates an example manufacturing process of a conductive connector. FIG. 9A illustrates an example process of forming a coating fabric. FIG. 9B illustrates an example process of coating a conductive woven fabric. FIGS. 9C and 9D illustrate an example process of forming a conductive connector using a conductive woven fabric and an elastic foam.

Referring to FIG. 8, in operation 801, a metal material may be plated on a woven layer. For example, the woven layer may be a fabric woven with weft and warp. The weft and warp may be formed from a fiber (e.g., the fiber 531a of FIG. 5). The woven layer may include a conductive coating (e.g., the conductive coating 531b of FIG. 5) surrounding the fiber 531a through the plating. The conductive coating 531b may include Ni, Cu, Au, and/or Ag. The conductive weft and warp including the conductive coating 531b may provide a conductive path.

Referring to FIGS. 8, 9A, and 9B, in operation 803, an elastic coating may be performed on a conductive woven fabric on which a metal material is plated.

For elastic coating, a polymer layer 901 to which an elastic coating material 903 is applied may be prepared. The polymer layer 901 may be moved by rollers r1, r2, and r3. As the coating material 903 moves through the roller r3 partially accommodated in a tank containing the coating material 903 for coating from among the rollers r1, r2, and r3, the coating material 903 may be applied to the polymer layer 901. In an embodiment, the polymer layer 901 may be formed from polyethylene terephthalate (PET).

Referring to FIGS. 8 and 9B, in operation 803, an elastic coating may be performed on a conductive woven fabric on which a metal material is plated. The elastic coated conductive woven fabric may function as a conductive outer jacket (e.g., the conductive outer jacket 531 of FIG. 5) of a conductive connector (e.g., the conductive connector 310 of FIG. 3). For example, a polymer material may be coated onto the conductive woven fabric to form an outer jacket of the conductive connector.

The polymer layer 901 (to which the coating material 903 is applied) may be disposed to be in contact with the conductive outer jacket 531 (or conductive woven fabric) and may pass through the rollers r4 and r5. The coating material 903 may be pressed onto the conductive outer jacket 531 by the rollers r4 and r5. The rollers r4 and r5 apply heat while the coating material 903 is pressed onto the conductive outer jacket 531, so a portion of the coating material 903 may permeate into a gap within the conductive outer jacket 531. For example, a portion of the coating material 903 may partially fill a gap of the conductive outer jacket 531. After the coating material 903 is pressed at the conductive outer jacket 531, the coating material 903 may be cured at room temperature to form the outer jacket of the conductive connector 310. The coating material 903 may be cured to function as a coating (e.g., the coating 532 of FIG. 5) of the conductive connector 310. After the coating material 903 is cured, the polymer layer 901 may be removed.

Referring to FIGS. 8 and 9C, in operation 805, an elastic foam may be attached onto an elastic coating layer disposed at an inner surface of the conductive outer jacket.

The adhesive 550 may be applied on the elastic coating 532 disposed in an inner surface of the conductive outer jacket 531 of the conductive connector 310. The adhesive 550 may be positioned on the elastic coating 532, and the elastic coating 532 may be configured to limit the adhesive 550 from leaking to the outer surface of the conductive outer jacket 531.

The adhesive 550 may be applied to the entire surface of the elastic coating 532. The interior part 510 of the conductive connector 310, which is formed of an elastic foam, may be disposed on the elastic coating 532 to which the adhesive 550 is applied. The elastic foam may be attached to the elastic coating 532 (or an inner surface of the conductive outer jacket 531 or an inner surface of the exterior part 530) by the adhesive 550.

Referring to FIGS. 8 and 9D, in operation 807, the elastic foam attached to the elastic coating layer may be surrounded with an outer jacket of the conductive connector to form a conductive connector.

The outer jacket 531 (or the exterior part 530) of the conductive connector 310 may surround the outer surface of the interior part 510 formed from the elastic foam. The conductive connector 310 in which the exterior part 530 surround the interior part 510 may include the interior part 510 having the elastic foam, the adhesive 550, and the exterior part 530.

The adhesive 550 may be applied along the outer surface of the interior part 510 (or elastic foam). For example, the adhesive 550 may be disposed on a surface of the interior part 510 (or elastic foam) facing a conductive layer (e.g., the conductive layer 411 of FIG. 4) of a display (e.g., the display 410 of FIG. 4) and another surface of the interior part 510 (or elastic foam) facing a conductive portion (e.g., the conductive portion 421 of FIG. 4) of a bracket (e.g., the bracket 420 of FIG. 4).

The exterior part 530 may include a conductive outer jacket 531 and a coating 532. A portion of the coating 532 may fill a groove portion or gap formed on an outer surface of the conductive outer jacket 531 through thermal transfer in operation 803.

The coating 532 may be disposed on an outer surface of the adhesive 550. For example, the coating 532 may partially surround the outer surface of the adhesive 550. Since the adhesive 550 is applied to an outer surface of the coating 532, and the exterior part 530 including the coating 532 to which the adhesive 550 is applied surrounds a lateral surface of the interior part 510, so the coating 532 may be disposed at the outer surface of the adhesive 550 in a state that the conductive connector 310 is completed. The coating 532 may be referred to as a coating layer or a coating portion in terms of being applied to the conductive outer jacket 531 of the exterior part 530 and forming a single layer.

The conductive outer jacket 531 may be disposed along an outer surface of the coating 532. When assembling an electronic device (e.g., the electronic device 100 of FIG. 1), the conductive outer jacket 531 may provide a conductive path between the conductive portion 421 of the bracket 420 and the conductive layer 411 of the display 410 by contacting with the conductive portion 421 of the bracket 420 and the conductive layer 411 of the display 410.

According to an embodiment, the electronic device may extend a ground by electrically connecting the conductive portion of the bracket and the conductive layer of the display by reducing oxidation of the outer surface of the conductive connector.

According to an embodiment, the electronic device may provide a stable electrical connection between the conductive portion and the conductive layer by including a conductive connector having elasticity.

According to an embodiment, as a fiber of the conductive connector has elasticity, a restoration speed of the conductive connector may be improved, and low resistance may be maintained. Since the conductive connector includes a coating having elasticity, it may be possible to prevent the formation of an oxide film on an outer surface of the conductive connector and reduce a loss of the plating layer of the conductive connector, by improving the elasticity of the conductive connector and reducing the leakage of the carboxyl group, which is a low molecular weight component of the adhesive.

The technical problems to be achieved in this document are not limited to those described above, and other technical problems not mentioned herein will be clearly understood by those having ordinary knowledge in the art to which the present disclosure belongs, from the following description.

According to the above-described embodiment, an electronic device (e.g., the electronic device 100 of FIG. 1) may include a bracket (e.g., the bracket 420 of FIG. 4) including a conductive portion (e.g., the conductive portion 421 of FIG. 4), a display (e.g., the display 410 of FIG. 4) including a conductive layer (e.g., the conductive layer 411 of FIG. 4). The electronic device may further include a conductive connector (e.g., the conductive connector 310 of FIG. 4). The conductive connector may be disposed between the conductive layer of the display and the conductive portion of the bracket. The conductive connector may be in contact with the conductive layer of the display. The electronic device may further include a conductive adhesive (e.g., the conductive adhesive 570 of FIG. 5). The conductive adhesive may attach the conductive connector to the conductive portion of the bracket. The conductive connector may include an interior part (e.g., the interior part 510 of FIG. 5) including an elastic foam, an exterior part (e.g., the exterior part 530 of FIG. 5) including a conductive woven fabric, a coating part (e.g., the coating 532 of FIG. 5) attached to an inner surface of the conductive woven fabric, and an adhesive (e.g., the adhesive 550 of FIG. 5) attaching the interior part to the coating part attached to the exterior part.

According to an embodiment, the conductive woven fabric (e.g., the conductive outer jacket 531 of FIG. 5) may include a conductive warp (e.g., the conductive warp 711 of FIG. 7), a conductive weft (e.g., the conductive weft 712 of FIG. 7), and at least one non-conductive portion positioned in one or more gaps (e.g., the gap “g” of FIG. 7) defined by the conductive warp and the conductive weft. The at least one non-conductive portion and the coating portion may be formed of an elastic material.

According to an embodiment, each of the conductive warp and the conductive weft may include a fiber (e.g., the fiber 531a of FIG. 5) and a conductive coating (e.g., the conductive coating 531b of FIG. 5) laterally surrounding the fiber. For example, at least one of the conductive warp and the conductive weft may comprise a fiber and a conductive coating laterally surrounding the fiber.

According to an embodiment, the conductive connector may include a conductive layer (e.g., the conductive layer 590 of FIG. 5), contacted with the conductive adhesive, disposed on a surface of the exterior part.

According to an embodiment, the conductive coating may be formed from Ni, Cu, Au and/or Ag. The conductive layer of the conductive connector may be formed from Au and/or Ag to provide resistance of chemical reactions by a material included in the conductive adhesive. For example, the conductive coating may comprise Ni, Cu, Au or Ag. The conductive layer of the conductive connector may comprise Au or Ag to have resistance of chemical reactions by a material in the conductive adhesive.

According to an embodiment, the coating portion at least partially may fill the one or more gaps defined by the conductive woven fabric.

According to an embodiment, the conductive adhesive fills a portion of the one or more gaps positioned on an outer surface of the exterior part, and another portion of the one or more gaps positioned on the outer surface of the exterior part may be empty. The portion of the one or more gaps may face the conductive portion of the bracket.

According to an embodiment, the conductive layer of the display and the conductive portion of the bracket, connected each other by of the conductive connector may be configured to function as a ground.

According to an embodiment, the elastic foam and the elastic material may include polyurethane (PU).

According to an embodiment, the adhesive of the conductive connector may include an acryl oligomer, an acryl copolymer, a tackifier, or a combination of these adhesive components.

According to an embodiment, the coating portion may be configured to limit the adhesive from flowing through the one or more gaps of the exterior part toward the display or the conductive adhesive.

According to an embodiment, the conductive connector may be compressed by pressure from the bracket and the display.

According to an embodiment, the conductive connector may have hexahedron shape.

According to an embodiment, the exterior part may be disposed on an upper surface of the conductive connector facing the conductive layer of the display, a lower surface facing the conductive portion of the bracket, and two lateral surfaces of four lateral surfaces between the upper surface and the lower surface, the two lateral surfaces spaced apart from each other.

According to an embodiment, a thickness of the elastic foam may be 400 micrometers to 600 micrometers, a thickness of the adhesive may be 5 micrometers to 10 micrometers, a thickness of the coating portion may be 3 micrometers to 5 micrometers, a thickness of the conductive woven fabric may be 20 micrometers to 25 micrometers, and a thickness of the conductive adhesive may be 5 micrometers to 12 micrometers.

According to an embodiment, a surface of the conductive connector may have irregularities by weaving the conductive warp and the conductive weft, included in the exterior part. The conductive connector may provide a large contact area between the outer surface of the exterior part and the conductive adhesive through the irregularities of the surface of the conductive connector.

According to the above-described embodiment, an electronic device (e.g., the electronic device 100 of FIG. 4) may include a bracket (e.g., the bracket 420 of FIG. 4), a display (e.g., the display 410 of FIG. 4) disposed on the bracket, and a conductive connector (e.g., the conductive connector 310 of FIG. 4) electrically connecting a conductive portion (e.g., the conductive portion 421 of FIG. 4) of the bracket and a conductive layer (e.g., conductive layer 411 of FIG. 4) of the display facing the conductive portion of the bracket. The conductive connector may include an elastic foam (e.g., the interior part 510 of FIG. 5), an adhesive (e.g., the adhesive 550 of FIG. 5) disposed on a first surface of the elastic foam facing the conductive layer of the display and on a second surface of the elastic foam facing the conductive portion of the bracket, a coating (e.g., the coating 532 of FIG. 5) disposed on an outer surface of the adhesive, and a conductive outer jacket (e.g., the conductive outer jacket 531 of FIG. 5), disposed along an outer surface of the coating, in contact with the conductive portion of the bracket and the conductive layer of the display, and providing a conductive path between the conductive portion of the bracket and the conductive layer of the display. A portion of the coating may fill a groove part formed at an outer surface of the conductive outer jacket.

According to an embodiment, the conductive outer jacket may be woven by a plurality of conductive fibers.

According to an embodiment, the electronic device may further comprise a conductive adhesive attaching the conductive connector to the conductive portion of the bracket. The conductive connector may include a conductive layer, disposed on a surface of the exterior part, in contact with the conductive adhesive.

According to an embodiment, the conductive connector may be compressed by pressure from the bracket and the display.

According to an embodiment, the coating may be configured to limit the adhesive from flowing through the conductive outer jacket toward the bracket or the display.

According to an embodiment, the electronic device may further comprise a conductive adhesive attaching the conductive connector to the conductive portion of the bracket.

The effects that can be obtained from the present disclosure are not limited to those described above, and any other effects not mentioned herein will be clearly understood by those having ordinary knowledge in the art to which the present disclosure belongs, from the following description.

FIG. 10 is a block diagram illustrating an electronic device 1001 in a network environment 1000 according to various embodiments.

Referring to FIG. 10, the electronic device 1001 in the network environment 1000 may communicate with an electronic device 1002 via a first network 1098 (e.g., a short-range wireless communication network), or at least one of an electronic device 1004 or a server 1008 via a second network 1099 (e.g., a long-range wireless communication network). According to an embodiment, the electronic device 1001 may communicate with the electronic device 1004 via the server 1008. According to an embodiment, the electronic device 1001 may include a processor 1020, memory 1030, an input module 1050, a sound output module 1055, a display module 1060, an audio module 1070, a sensor module 1076, an interface 1077, a connecting terminal 1078, a haptic module 1079, a camera module 1080, a power management module 1088, a battery 1089, a communication module 1090, a subscriber identification module (SIM) 1096, or an antenna module 1097. In some embodiments, at least one of the components (e.g., the connecting terminal 1078) may be omitted from the electronic device 1001, or one or more other components may be added in the electronic device 1001. In some embodiments, some of the components (e.g., the sensor module 1076, the camera module 1080, or the antenna module 1097) may be implemented as a single component (e.g., the display module 1060).

The processor 1020 may execute, for example, software (e.g., a program 1040) to control at least one other component (e.g., a hardware or software component) of the electronic device 1001 coupled with the processor 1020, and may perform various data processing or computation. According to an embodiment, as at least part of the data processing or computation, the processor 1020 may store a command or data received from another component (e.g., the sensor module 1076 or the communication module 1090) in volatile memory 1032, process the command or the data stored in the volatile memory 1032, and store resulting data in non-volatile memory 1034. According to an embodiment, the processor 1020 may include a main processor 1021 (e.g., a central processing unit (CPU) or an application processor (AP)), or an auxiliary processor 1023 (e.g., a graphics processing unit (GPU), a neural processing unit (NPU), an image signal processor (ISP), a sensor hub processor, or a communication processor (CP)) that is operable independently from, or in conjunction with, the main processor 1021. For example, when the electronic device 1001 includes the main processor 1021 and the auxiliary processor 1023, the auxiliary processor 1023 may be adapted to consume less power than the main processor 1021, or to be specific to a specified function. The auxiliary processor 1023 may be implemented as separate from, or as part of the main processor 1021.

The auxiliary processor 1023 may control at least some of functions or states related to at least one component (e.g., the display module 1060, the sensor module 1076, or the communication module 1090) among the components of the electronic device 1001, instead of the main processor 1021 while the main processor 1021 is in an inactive (e.g., sleep) state, or together with the main processor 1021 while the main processor 1021 is in an active state (e.g., executing an application). According to an embodiment, the auxiliary processor 1023 (e.g., an image signal processor or a communication processor) may be implemented as part of another component (e.g., the camera module 1080 or the communication module 1090) functionally related to the auxiliary processor 1023. According to an embodiment, the auxiliary processor 1023 (e.g., the neural processing unit) may include a hardware structure specified for artificial intelligence model processing. An artificial intelligence model may be generated by machine learning. Such learning may be performed, e.g., by the electronic device 1001 where the artificial intelligence is performed or via a separate server (e.g., the server 1008). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 1030 may store various data used by at least one component (e.g., the processor 1020 or the sensor module 1076) of the electronic device 1001. The various data may include, for example, software (e.g., the program 1040) and input data or output data for a command related thereto. The memory 1030 may include the volatile memory 1032 or the non-volatile memory 1034.

The program 1040 may be stored in the memory 1030 as software, and may include, for example, an operating system (OS) 1042, middleware 1044, or an application 1046.

The input module 1050 may receive a command or data to be used by another component (e.g., the processor 1020) of the electronic device 1001, from the outside (e.g., a user) of the electronic device 1001. The input module 1050 may include, for example, a microphone, a mouse, a keyboard, a key (e.g., a button), or a digital pen (e.g., a stylus pen).

The sound output module 1055 may output sound signals to the outside of the electronic device 1001. The sound output module 1055 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 1060 may visually provide information to the outside (e.g., a user) of the electronic device 1001. The display module 1060 may include, for example, a display, a hologram device, or a projector and control circuitry to control a corresponding one of the display, hologram device, and projector. According to an embodiment, the display module 1060 may include a touch sensor adapted to detect a touch, or a pressure sensor adapted to measure the intensity of force incurred by the touch.

The audio module 1070 may convert a sound into an electrical signal and vice versa. According to an embodiment, the audio module 1070 may obtain the sound via the input module 1050, or output the sound via the sound output module 1055 or a headphone of an external electronic device (e.g., an electronic device 1002) directly (e.g., wiredly) or wirelessly coupled with the electronic device 1001.

The sensor module 1076 may detect an operational state (e.g., power or temperature) of the electronic device 1001 or an environmental state (e.g., a state of a user) external to the electronic device 1001, and then generate an electrical signal or data value corresponding to the detected state. According to an embodiment, the sensor module 1076 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1077 may support one or more specified protocols to be used for the electronic device 1001 to be coupled with the external electronic device (e.g., the electronic device 1002) directly (e.g., wiredly) or wirelessly. According to an embodiment, the interface 1077 may include, for example, a high definition multimedia interface (HDMI), a universal serial bus (USB) interface, a secure digital (SD) card interface, or an audio interface.

A connecting terminal 1078 may include a connector via which the electronic device 1001 may be physically connected with the external electronic device (e.g., the electronic device 1002). According to an embodiment, the connecting terminal 1078 may include, for example, an HDMI connector, a USB connector, a SD card connector, or an audio connector (e.g., a headphone connector).

The haptic module 1079 may convert an electrical signal into a mechanical stimulus (e.g., a vibration or a movement) or electrical stimulus which may be recognized by a user via his tactile sensation or kinesthetic sensation. According to an embodiment, the haptic module 1079 may include, for example, a motor, a piezoelectric element, or an electric stimulator.

The camera module 1080 may capture a still image or moving images. According to an embodiment, the camera module 1080 may include one or more lenses, image sensors, image signal processors, or flashes.

The power management module 1088 may manage power supplied to the electronic device 1001. According to an embodiment, the power management module 1088 may be implemented as at least part of, for example, a power management integrated circuit (PMIC).

The battery 1089 may supply power to at least one component of the electronic device 1001. According to an embodiment, the battery 1089 may include, for example, a primary cell which is not rechargeable, a secondary cell which is rechargeable, or a fuel cell.

The communication module 1090 may support establishing a direct (e.g., wired) communication channel or a wireless communication channel between the electronic device 1001 and the external electronic device (e.g., the electronic device 1002, the electronic device 1004, or the server 1008) and performing communication via the established communication channel. The communication module 1090 may include one or more communication processors that are operable independently from the processor 1020 (e.g., the application processor (AP)) and supports a direct (e.g., wired) communication or a wireless communication. According to an embodiment, the communication module 1090 may include a wireless communication module 1092 (e.g., a cellular communication module, a short-range wireless communication module, or a global navigation satellite system (GNSS) communication module) or a wired communication module 1094 (e.g., a local area network (LAN) communication module or a power line communication (PLC) module). A corresponding one of these communication modules may communicate with the external electronic device via the first network 1098 (e.g., a short-range communication network, such as Bluetooth™, wireless-fidelity (Wi-Fi) direct, or infrared data association (IrDA)) or the second network 1099 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 1092 may identify and authenticate the electronic device 1001 in a communication network, such as the first network 1098 or the second network 1099, using subscriber information (e.g., international mobile subscriber identity (IMSI)) stored in the subscriber identification module 1096.

The wireless communication module 1092 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 1092 may support a high-frequency band (e.g., the mmWave band) to achieve, e.g., a high data transmission rate. The wireless communication module 1092 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 1092 may support various requirements specified in the electronic device 1001, an external electronic device (e.g., the electronic device 1004), or a network system (e.g., the second network 1099). According to an embodiment, the wireless communication module 1092 may support a peak data rate (e.g., 20 Gbps or more) for implementing eMBB, loss coverage (e.g., 1064 dB or less) for implementing mMTC, or U-plane latency (e.g., 0.5 ms or less for each of downlink (DL) and uplink (UL), or a round trip of 10 ms or less) for implementing URLLC.

The antenna module 1097 may transmit or receive a signal or power to or from the outside (e.g., the external electronic device) of the electronic device 1001. According to an embodiment, the antenna module 1097 may include an antenna including a radiating element composed of a conductive material or a conductive pattern formed in or on a substrate (e.g., a printed circuit board (PCB)). According to an embodiment, the antenna module 1097 may include a plurality of antennas (e.g., array antennas). In such a case, at least one antenna appropriate for a communication scheme used in the communication network, such as the first network 1098 or the second network 1099, may be selected, for example, by the communication module 1090 (e.g., the wireless communication module 1092) from the plurality of antennas. The signal or the power may then be transmitted or received between the communication module 1090 and the external electronic device via the selected at least one antenna. According to an embodiment, another component (e.g., a radio frequency integrated circuit (RFIC)) other than the radiating element may be additionally formed as part of the antenna module 1097.

According to various embodiments, the antenna module 1097 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) between the above-described components via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 1001 and the external electronic device 1004 via the server 1008 coupled with the second network 1099. Each of the electronic devices 1002 or 1004 may be a device of a same type as, or a different type, from the electronic device 1001. According to an embodiment, all or some of operations to be executed at the electronic device 1001 may be executed at one or more of the external electronic devices 1002, 1004, or 1008. For example, if the electronic device 1001 performs a function or a service automatically, or in response to a request from a user or another device, the electronic device 1001, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 1001. The electronic device 1001 may provide the outcome, with or without further processing of the outcome, as at least part of a reply to the request. To that end, a cloud computing, distributed computing, mobile edge computing (MEC), or client-server computing technology may be used, for example. The electronic device 1001 may provide ultra-low-latency services using, e.g., distributed computing or mobile edge computing. In another embodiment, the external electronic device 1004 may include an internet-of-things (IoT) device. The server 1008 may be an intelligent server using machine learning and/or a neural network. According to an embodiment, the external electronic device 1004 or the server 1008 may be included in the second network 1099. The electronic device 1001 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “Ist” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part of the above components, adapted to perform one or more functions. For example, according to an embodiment, the module may be implemented in a form of an application-specific integrated circuit (ASIC).

Various embodiments as set forth herein may be implemented as software (e.g., the program 1040) including one or more instructions that are stored in a storage medium (e.g., internal memory 1036 or external memory 1038) that is readable by a machine (e.g., the electronic device 1001). For example, a processor (e.g., the processor 1020) of the machine (e.g., the electronic device 1001) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

No claim element is to be construed under the provisions of 35 U.S.C. § 112, sixth paragraph, unless the element is expressly recited using the phrase “means for” or “means.”

What is claimed is:

1. An electronic device comprising:
a bracket comprising a conductive portion;
a display comprising a conductive layer;
a conductive connector, disposed between the conductive layer of the display and the conductive portion of the bracket, contacted with the conductive layer of the display; and
a conductive adhesive attaching the conductive connector to the conductive portion of the bracket,
wherein the conductive connector comprises:
an interior part comprising an elastic foam,
an exterior part comprising a conductive woven fabric,
a coating portion attached to an inner surface of the conductive woven fabric of the exterior part, and
an adhesive attaching the interior part to the coating portion.

2. The electronic device of claim 1, wherein the conductive woven fabric comprises:
a conductive warp,
a conductive weft, and
at least one non-conductive portion disposed in one or more gaps defined by the conductive warp and the conductive weft, and
wherein the coating portion is formed from an elastic material.

3. The electronic device of claim 2, wherein at least one of the conductive warp and the conductive weft comprises a fiber and a conductive coating laterally surrounding the fiber.

4. The electronic device of claim 1, wherein the conductive connector comprises a conductive layer, disposed on a surface of the exterior part, contacted with the conductive adhesive.

5. The electronic device of claim 4, wherein the conductive coating comprises Ni, Cu, Au and/or Ag, and
wherein the conductive layer of the conductive connector comprises Au and/or Ag to have resistance of chemical reactions by a material in the conductive adhesive.

6. The electronic device of claim 1, wherein the coating portion at least partially fills one or more gaps defined by the conductive woven fabric.

7. The electronic device of claim 1, wherein the conductive adhesive fills a portion of one or more gaps, that is defined by the conductive woven fabric, on an outer surface of the exterior part, and another portion of the one or more gaps on the outer surface of the exterior part is empty, and
wherein the portion of the one or more gaps faces the conductive portion of the bracket.

8. The electronic device of claim 1, wherein the conductive layer of the display and the conductive portion of the bracket are connected each other by of the conductive connector, and
wherein the conductive layer of the display and the conductive portion of the bracket are configured to function as a ground.

9. The electronic device of claim 1, wherein the elastic foam comprises polyurethane (PU).

10. The electronic device of claim 1, wherein the adhesive of the conductive connector comprises an acryl oligomer, an acryl copolymer, a tackifier, or a combination thereof.

11. The electronic device of claim 1, wherein the coating portion is configured to limit the adhesive from flowing through one or more gaps of the exterior part, that is defined by the conductive woven fabric, toward the display or the conductive adhesive.

12. The electronic device of claim 1, wherein the conductive connector is compressed by pressure from the bracket and the display.

13. The electronic device of claim 1, wherein the conductive connector has hexahedron shape, and
wherein the exterior part is disposed on an upper surface of the conductive connector facing the conductive layer of the display, a lower surface facing the conductive portion of the bracket, and two lateral surfaces of four lateral surfaces between the upper surface and the lower surface, the two lateral surfaces being spaced apart from each other.

14. The electronic device of claim 1, wherein a thickness of the elastic foam is 400 micrometers to 600 micrometers,
wherein a thickness of the adhesive is 5 micrometers to 10 micrometers,
wherein a thickness of the coating portion is 3 micrometers to 5 micrometers,
wherein a thickness of the conductive woven fabric is 20 micrometers to 25 micrometers, and
wherein a thickness of the conductive adhesive is 5 micrometers to 12 micrometers.

15. The electronic device of claim 1, wherein a surface of the conductive connector has irregularities by weaving the conductive warp and the conductive weft, included in the exterior part, and
wherein the conductive connector has a contact area between the outer surface of the exterior part and the conductive adhesive through the irregularities of the surface of the conductive connector.

16. An electronic device comprising:
a bracket;
a display on the bracket; and
a conductive connector electrically connecting a conductive portion of the bracket and a conductive layer of the display facing the conductive portion of the bracket,
wherein the conductive connector comprises:
an elastic foam,
an adhesive on a first surface of the elastic foam facing the conductive layer of the display and a second surface of the elastic foam facing the conductive portion of the bracket,
a coating at an outer surface of the adhesive, and
a conductive outer jacket disposed along an outer surface of the coating and contacted with the conductive portion of the bracket and the conductive layer of the display, the conductive outer jacket providing a conductive path between the conductive portion of the bracket and the conductive layer of the display, and
wherein a portion of the coating fills a groove portion at an outer surface of the conductive outer jacket.

17. The electronic device of claim 16, wherein the conductive outer jacket is woven by a plurality of conductive fibers.

18. The electronic device of claim 16, further comprising a conductive adhesive attaching the conductive connector to the conductive portion of the bracket, wherein the conductive connector comprises a conductive layer on a surface of an exterior part and contacting the conductive adhesive.

19. The electronic device of claim 16, wherein the conductive connector is compressed by pressure from the bracket and the display, and
wherein the coating is configured to limit the adhesive from flowing through the conductive outer jacket toward the bracket or the display.

20. The electronic device of claim 16, further comprising a conductive adhesive attaching the conductive connector to the conductive portion of the bracket.
